(19) United States
(12) Patent Application Publication
(10) Pub. No.: US 2005/0084993 A1
(43) Pub. Date: Apr. 21, 2005

(54) Light-guiding bodies and method for the production thereof

(75) Inventors: Jann Schmidt, Darmstadt (DE); Markus Parusel, Messel (DE); Herbert Groothues, Weiterstadt (DE); Guenther Ittmann, Gross-Umstadt (DE)

Correspondence Address: OBLON, SPIVAK, MCCLELLAND, MAIER & NEUSTADT, P.C., 1940 DUKE STREET, ALEXANDRIA, VA, 22314, US

(73) Assignee: Roehm Gbmh & Co. KG, Darnstadt (DE)

(21) Appl. No.: 10/501,925

(22) PCT Filed: May 6, 2003
(86) PCT No.: PCT/EP03/04719

(30) Foreign Application Priority Data
May 16, 2002 (DE) 102 22 250.9

(51) Int. Cl. H01L 21/00

(52) U.S. Cl. 438/22

(57) ABSTRACT

The present invention relates to a [lacuna] having at least one light-entry surface and at least one light-exit surface, the ratio of the light-exit surface area to the light-entry surface area being at least 4, comprising at least one light-guiding layer, characterized in that the light-guiding layer comprises at least 60% by weight, expressed in terms of the weight of the light-guiding layer, of polymethyl methacrylate and from 0.0001 to 0.2% by weight, expressed in terms of the weight of the light-guiding layer, of spherical particles with an average diameter in the range of from 0.3 to 40 μm, and the light-exit surface of the light-guiding layer is provided with structurings.

The present invention relates to light-guide bodies, which have at least one light-entry surface and at least one light-exit surface as well as at least one light-guiding layer, the ratio of the light-exit surface area to the light-entry surface area being at least 4.

Such light-guide bodies are known per se. For instance, a transparent plate may be provided with notches at which the light is extracted normal to the propagation direction. Such light-guide bodies are the subject of EP 800 036. When the notches are distributed uniformly, however, the light-guide bodies exhibit a reduction in luminance with increasing distance from the lighting means. As a solution to this problem, nonuniform surface structures are applied to the light guide bodies, the density of the notches increasing with the distance from the lighting means. This effect is nevertheless compromised by the statistical damage to the surface which occurs in the course of time. In addition, the luminance of large plates is relatively small.

In addition, light-guide bodies which use polymer particles as scattering bodies are known from EP 656 584. The problem with these plates is their nonuniform luminance distribution.

Furthermore, light-guide bodies which have a particle-free light-guiding layer made of polymethyl methacrylate, onto which a diffusely configured layer is applied, are known from EP 1022129. The diffusely configured layer, which has a thickness in the range of from 10 to ˜1500 μm, comprises barium sulfate particles. According to this principle, the light is guided via the PMMA layer, the extraction taking place through the diffuse layer. However, the light extraction can scarcely be controlled since only the light which has penetrated the boundary layer with the diffusely configured layer is scattered normal to the propagation direction. Therefore, this does not involve perturbation inside the light-guiding layer, but rather diffuse back-reflection. In addition, the reduction in the light intensity is very great, as substantiated by the examples.

This entails a low luminance at large range from the light source, which is insufficient for many applications. The low brightness at a sizeable distance from the light source of the light-guide body according to EP 1022129 furthermore leads to a high sensitivity with respect to the formation of scratches on the exit surface for the light. Such scratches can be produced both by weathering and by mechanical action. The fact that these scratches scatter the light is problematic in this case. The teaching of EP 800 036 is based on this principle. These defects are not particularly noticeable at a high level of light extraction. At low brightnesses, however, they are seen as a perturbation.

In view of the prior art cited and discussed here, it was therefore an object of the present invention to provide light-guide bodies which have particularly uniform luminance. In this case, the light-guide bodies should permit light extraction which can be adapted to requirements.

Furthermore, the luminance should be as constant as possible over the entire area of the light-exit surface, and this constancy should also remain unaffected by the statistical formation of surface scratches.

It was another object of the invention for the light-guide bodies to have a high durability, in particular a high resistance to UV radiation or weathering.

It was, in addition, an object of the invention to provide light-guide bodies which can be produced in a particularly straightforward way. For instance, it should be possible to produce the light-guide bodies, in particular, by extrusion, injection molding and by molding processes.

Furthermore, it was therefore an object of the present invention to provide light-guide bodies which can be produced inexpensively.

It was another object of the present invention to provide light-guide bodies which exhibit outstanding mechanical properties. This property is, in particular, important for applications in which the light-guide body needs to have high stability against impact.

It was another object of the present invention to provide light-guide bodies which can readily be matched to requirements in terms of size and shape.

These objects and others which, although not actually mentioned explicitly, can be inferred as obvious from the contexts discussed here or necessarily result therefrom, are achieved by the light-guide bodies described in claim 1. Expedient refinements of the light-guide bodies according to the invention are protected in the dependent claims referring to claim 1.

With respect to production processes, claims 16 and 17 provide a solution to the underlying object.

The fact that the light-guiding layer of a light-guide body comprises at least 60% by weight, expressed in terms of the weight of the light-guiding layer, of polymethyl methacrylate and from 0.0001 to 0.2% by weight, expressed in terms of the weight of the light-guiding layer, of spherical particles with an average diameter in the range of from 0.3 to 40 μm, and the light-exit surface of the light-guiding layer is provided with structurings, the light-guiding body comprising at least one light-entry surface and at least one light-exit surface, the ratio of the light-exit surface area to the light-entry surface area being at least 4, makes it possible to provide light-guide bodies which have particularly uniform luminance.

The measures according to the invention provide, inter alia, the following advantages in particular:
The light-guide bodies of the present invention can be produced in a particularly straightforward way. For instance, the light-guide bodies can be produced by extrusion, injection molding and by molding processes.
The luminance distribution of the present light-guide bodies is relatively insensitive with respect to the formation of scratches on the surface.
The light-guide bodies according to the invention exhibit a high resistance to UV radiation.
In addition, light-guide bodies according to the invention exhibit a particularly uniform luminance distribution. In this case, light-guide bodies of differing size can be produced without the luminance distribution being critical to a particular extent.
Furthermore, the light-guide bodies of the present invention exhibit a particularly constant-color light, so that no yellow impression is incurred with increasing distance from the light source.
The brightness of the light-guide bodies can be adapted to requirements. For instance, it is also possible to produce large plates with a very high luminance.
The light-guide bodies of the present invention have good mechanical properties.

The light-guiding layer of the light-guide body according to the present invention has from 0.0001 to 0.2, preferably from 0.0005 to 0.08 and particularly preferably from 0.0008 to 0.01% by weight, expressed in terms of the weight of the light-guiding layer, of spherical particles.

Term “spherical” in the scope of the present invention denotes that the particles preferably have a ball-shaped configuration, although it is obvious to the person skilled in the art that particles with another configuration may be obtained owing to the production methods, or that the shape of the particles may deviate from the ideal ball configuration.

Accordingly, the term “spherical” means that the ratio of the largest dimension of the particles to the smallest dimension is at most 4, preferably at most 2, these dimensions being respectively measured through the centre of mass of the particles. Advantageously, at least 70%, particularly preferably at least 90%, expressed in terms of the number of particles, are spherical.

The particles have an average diameter (weight average), in the range of from 0.3 to 40 μm, preferably from 0.7 to 20 μm, in particular in the range of from 1.4 to 10 μm. Advantageously, 75% of the particles are in the range of from 0.3 to 40 μm, in particular from 1.4 to 10 μm. The particle size is determined by means of an x-ray sedigraph. In this case, the settling behavior of plastic particles in the gravitational field is studied by means of x-rays. The particle size is deduced with the aid of the x-ray transparency.

The particles which may be used according to the invention are not restricted in any particular way. These particles are advantageously made of barium sulfate and/or plastic.

Barium sulfate particles which have the aforementioned properties are known per se, and they are commercially available, inter alia, from Sachtleben Chemie GmbH, D-47184 Duisburg. Various production methods are furthermore known. Barium sulfate particles preferably have a size in the range of from 0.7 to 6 μm.

Furthermore, it is also possible to use particles which are made of plastic. In this case, the type of plastic from which the particles are made is not critical, although the plastic must be incompatible with the polymers of the matrix so that a phase boundary at which refraction of the light takes place is obtained.

Accordingly, the refractive index of the plastic particles has a refraction index nₒ, measured at the Na-D line (589 nm) and at 20° C., which is higher than the refraction index n₀ of the matrix plastic by 0.01 units, advantageously 0.02 units.

Preferred plastic particles are made up of:
b1) from 0 to 60 parts by weight of an acrylate or methacrylate with from 1 to 12 C atoms in the aliphatic ester residue, examples being: methyl (meth)acrylate, ethyl (meth)acrylate, n-propyl (meth)acrylate, i-propyl (meth)acrylate, n-butyl (meth)acrylate, i-butyl (meth)acrylate, tert.-butyl (meth)acrylate, cyclohexyl (meth)acrylate, 3,3,5-trimethylcyclohexyl (meth)acrylate, 2-ethylhexyl (meth)acrylate, norbornyl (meth)acrylate or isobornyl (meth)acrylate;
b2) from 25 to 99.9 parts by weight of comonomers which have aromatic groups as substituents and which are copolymerizable with the monomers b1), for example styrene, α-methyl styrene, ring-substituted styrenes, phenyl (meth)acrylate, benzyl (meth)acrylate, 2-phenylethyl (meth)acrylate, 3-phenylpropyl (meth)acrylate Or vinyl benzoate; as well as
b3) from 0.1 to 15 parts by weight of crosslinking comonomers which have at least two ethyenically unsaturated groups that are radical-copolymerizingable with b1) and b2), for example divinylbenzene, glycol di(meth)acrylate 1,4-butandiol di(meth)acrylate, allyl (meth)acrylate, triallyl cyanurate, diallyl phthalate, diallyl succinate, pentaerythrite tetra(meth)acrylate or trimethylolpropane tri(meth)acrylate, the comonomers b1), b2) and b3) adding up to 100 parts by weight.

Mixtures from which the particles are made particularly preferably have at least 80% by weight of styrene and at least 0.5% by weight of divinylbenzene.

Such plastic particles preferably have a size in the range of from 2 to 20 μm, in particular from 4 to 12 μm.

The production of crosslinked plastic articles is known in the specialist field. For instance, the scattering particles may be produced by emulsion polymerization, as described for example in EP-A 342 283 or EP-A 269 324, more particularly preferably by organic-phase polymerization, as described for example in the German patent application P 43 27 464.1; in the latter polymerization technique, particularly narrow particle size distributions or, put another way, particularly small deviations of the particle diameters from the average particle diameter, are obtained.

It is particularly preferable to use plastic particles which have a thermal stability of at least 200° C., in particular at least 250° C., but without thereby implying any limitation. In this case, the term “thermally stable” means that the particles suffer substantially no thermally induced degradation. Thermally induced degradation undesirably leads to discolorations, so that the plastic material becomes unusable.

Particularly preferred particles are available, inter alia, from Sekisui under the brand names ®Techpolymer SBX-8 and ®Techpolymer SBX-12.

According to a particular aspect of the present invention, these particles are uniformly distributed in the plastic matrix, without significant aggregation or congregation of the particles taking place. “Uniformly distributed” means that the concentration of particles inside the plastic matrix is essentially constant.

According to the invention, the light-guiding layer comprises at least 60% by weight, expressed in terms of the weight of the light-guiding layer, of polymethyl methacrylate.

These polymers are generally obtained by radical polymerization of mixtures which contain methyl methacrylate. In general, these mixtures contain at least 40% by weight, preferably at least 60% by weight and particularly preferably at least 80%, expressed in terms of the weight of the monomers, of methyl methacrylate.

In addition, these mixtures may contain further (meth)acrylates, which are copolymerizable with methyl methacrylate. The expression “(meth)acrylates” covers methacrylates and acrylates as well as mixtures of the two.

These monomers are widely known. They include, inter alia,
(meth)acrylates which are derived from saturated alcohols, for example methyl acrylate, ethyl (meth)acrylate, propyl (meth)acrylate, n-butyl (meth)acrylate, tert.-butyl (meth)acrylate, pentyl (meth)acrylate and 2-ethylhexyl (meth)acrylate;
(meth)acrylates which are derived from unsaturated alcohols, for example oleyl (meth)acrylate, 2-propinyl (meth)acrylate, allyl (meth)acrylate, vinyl (meth) acrylate;
aryl (meth)acrylates, such as benzyl (meth)acrylate or phenyl (meth)acrylate, in which case the aryl radicals may be unsubstituted or substituted up to four times; cycloalkyl (meth)acrylates, such as 3-vinylcyclohexyl (meth)acrylate, bornyl (meth)acrylate;
hydroxyalkyl (meth)acrylates, such as 3-hydroxypropyl (meth)acrylate, 3,4-dihydroxybutyl (meth)acrylate, 2-hydroxyethyl (meth)acrylate, 2-hydroxypropyl (meth) acrylate;
glycol di(meth)acrylates, such as 1,4-butandiol (meth) acrylate,
(meth)acrylates of ether-alcohols, such as tetrahydofurfuryl (meth)acrylate, vinyloxy ethoxyethyl (meth) acrylate;
amides and nitriles of (meth)acrylic acid, such as N-(3-dimethylaminopropyl) (meth)acrylamide, N-(diethylphosphono) (meth)acrylamide, 1-methacryloylamido-2-methyl-2-propanol;
methacrylates containing sulfur, such as ethylsulfinyl (meth)acrylate, 4-thiocyanatobutyl (meth)acrylate, ethylsulfonylethyl (meth)acrylate, thiocyanatomethyl (meth)acrylate, methylsulfinylmethyl (meth)acrylate, Bis((meth)acryloyloxyethyl) sulfide;
polyvalent (meth)acrylates, such as trimethyloylpropane tri(meth)acrylate.

Besides the (meth)acrylates presented above, the compositions to be polymerized may also have other unsaturated monomers which are copolymerizable with methyl methacrylate and the aforementioned (meth) acrylates.

These include, inter alia, 1-alkenes, such as hex-1-ene, hept-1-ene; branched alkenes, for example vinyl cyclohexane, 3,3-dimethyl-1-propene, 3-methyl-1-diisobutylene, 4-methylpent-1-ene;
acrylonitrile; vinyl esters, such as vinyl acetate; styrene; substituted styrenes with an alkyl substituent in the side chain, for example the α-methyl styrene and α-ethyl styrene, substituted styrenes with an alkyl substituent in the ring, such as vinyl toluene and p-methyl styrene, halogenated styrenes, for example monochlorostyrenes, dichlorostyrenes, tribromostyrenes and tetrabromostyrenes;
heterocyclic vinyl compounds, such as 2-vinylpyridine, 3-vinylpyridine, 2-methyl-5-vinylpyridine, 3-ethyl-4-vinylpyridine, 2,3-dimethyl-5-vinylpyridine, vinyl pyrimidine, vinyl piperidine, 9-vinylcarbazole, 3-vinylcarbazole, 4-vinylcarbazole, 1-vinylimidazole, 2-methyl-1-vinylimidazole, N-vinylpyrrolidone, 2-vinylpyrrolidone, N-vinylpyrrolidine, 3-vinylpyrrolidine, N-vinylcaprolactam, N-vinylbutyrolactam, vinyloxolan, vinylfuran, vinylthiophene, vinylthiolane, vinylthiazoles and hydrated vinylthiazoles, vinyloxazoles and hydrated vinyloxazoles;
vinyl and isoprenyl ethers;
maleic acid derivatives, for example maleic anhydride, methylmaleic anhydride, maleinimide, methylmaleinimide; and dienes, for example divinylbenzene.

In general, these comonomers will be used in an amount of from 0 to 60% by weight, preferably 0 to 40% by weight and particularly preferably 0 to 20% by weight, expressed in terms of the weight of the monomers, and the compounds may be used individually or as a mixture.

The polymerization is generally started using known radical initiators. The preferred initiators include, inter alia, the azo initiators widely known in the specialist field, such as AIBN, and 1,1-azobiscyclohexane carbonitrile, as well as peroxy compounds, such as methyl ethyl ketone peroxide, acetylacetone peroxide, dilauryl peroxide, tert.-butyl per-2-ethylhexanoate, ketone peroxide, methylisobutyl ketone peroxide, cyclohexanone peroxide, dibenzoyl peroxide, tert.-butyl peroxybenzoate, tert.-butyl peroxyisopropyl carbonate, 2,5-bis(2-ethylhexanoylperoxy)-2,5-dimethylhexane, tert.-butyl peroxy-2-ethylhexanoate, tert.-butyl peroxy-3,5,5-trimethylhexanoate, dicumyl peroxide, 1-1-bis(tert.-butylperoxy)cyclohexane, 1-1-bis(tert.-butylperoxy)3,3,5-trimethylcyclohexane, cumyl hydroperoxide, tert.-butyl hydroperoxide, bis(4-tert.-butylcyclohexyl) peroxydicarbonate, mixtures of two or more of the aforementioned compounds with one another, as well as mixtures of the aforementioned compounds with unnamed compounds which can likewise form radicals.

These compounds are often used in an amount of from 0.01 to 10% by weight, preferably from 0.5 to 3% by weight, expressed in terms of the weight of the monomers.

In this case, it is possible to use various poly(meth)acrylates which differ, for example, by molecular weight or monomer composition.

In addition, the molding compositions may contain further polymers in order to modify the properties. These include, inter alia, polyacrylonitriles, polystyrenes, polyethers, polyesters, polycarbonates and polyvinyl chlorides. These polymers may be used individually or as a mixture, and copolymers which are derived from the aforementioned polymers may also be added to the molding compositions.

Such particularly preferred molding compositions are commercially available under the brand name PLEXIGLAS® from the company Röhm GmbH & Co. KG.

The weight average of the molecular weight M_{W} of the homo- and/or copolymers to be used according to the invention as matrix polymers can vary in wide ranges, the molecular weight usually being matched to the task and the method of processing the molding composition. In general, however, it is in the range of between 20,000 and 1,000,000 g/mol, preferably 50,000 to 500,000 g/mol and particularly preferably from 80,000 to 300,000 g/mol, but without thereby implying any limitation.

After addition of the particles, light-guiding layers can be produced from these molding compositions by conventional thermoplastic shaping methods. These include, in particular, extrusion and injection molding.

The light guiding layers of the present invention may furthermore be produced by molding processes. In this case, suitable acrylic resin mixtures are placed in a mold and polymerized.

A suitable acrylic resin comprises, for example,
A) 0.0001-0.2% by weight of spherical particles with an average diameter in the range of from 0.3 to 40 μm,
B) 40-99.9999% by weight of methyl methacrylate,
C) 0-59.9999% of comonomers,
D) 0-59.9999% of polymers which are soluble in (B) or (C), the components A) to D) adding up to 100%.

The acrylic resin furthermore has the initiators needed for polymerization. The components A to D and the initiators correspond to the compounds which are also used for the production of suitable polymethyl methacrylate molding compositions.

For curing, the so-called molding chamber method may for example be used (see, for example, DE 25 44 245, EP-B 570 782 or EP-A 656 548), in which the polymerization of a plastic disk takes place between two glass plates, which are sealed by a circumferential cord.

Accordingly to a particular embodiment of the present invention, the light-guiding layer has at least 70, preferably at least 80 and particularly preferably at least 90% by weight, expressed in terms of the light-guiding layer, of polymethyl methacrylate.

According to a particular aspect of the present invention, the poly(meth)acrylates of the light-guiding layer have a refractive index, measured at the Na-D line (589 nm) and at 20° C., in the range of from 1.48 to 1.54.

The molding compositions and the acrylic resins may contain customary additives of all types. These include, inter alia, antistatics, antioxidants, mold release agents, flameproofing agents, lubricants, colorants, flow enhancers, fillers, light stabilizers and organic phosphorus compounds, such as phosphites or phosphonates, pigments, anti-weathering agents and plasticizers. The amount of additives is, however, restricted to the intended purpose. For instance, the light-guiding property of the polymethyl methacrylate layer must not be impaired to greatly by additives.

The light-guiding layer generally has a transmission in the range of from 80 to 92%, preferably from 83 to 92, but without thereby implying any limitation. The transmission may be determined according to DIN 5036.

The thickness of the light-guiding layer is not critical. The thickness of the light-guiding layer is preferably in the range of from 2 to 100 mm, particularly preferably from 3 to 20 mm, but without thereby implying any limitation.

The light-guide body of the present invention has at least one light-entry surface and at least one light-exit surface.

The term “light-exit surface” in this case refers to a surface of the light-guide body which is suitable for emitting light. The light-entry surface is in turn capable of receiving light into the body, so that the light-guiding layer can distribute the introduced light over the entire light-exit surface. The light-guiding layer has a thickness of at least 2 mm. The particles lead to extraction of the light, so that light emerges over the entire light-exit surface.

In this case, the ratio of the light-exit surface area to the light-entry surface area is at least 4, preferably at least 20 and particularly preferably at least 80.

The effect of this is that the light-guide body of the present invention differs to a great extent from known covers for illumination bodies. These covers are distinguished by the fact that the light-entry surface is formed parallel with the light-exit surface, so that both surfaces have approximately the same size.

The light-exit surface of the light-guiding layer has structurings. The structurings may be obtained after having produced the plates, for example by pressure or other mechanical effects. The structuring may furthermore be achieved during production of the plates, by using molds which have a negative of the structuring. For example, etched glass plates may be used as a mold in the aforementioned molding chamber method.

The form of the structuring is not critical. What is essential is that the light-exit surface comprises defects which are capable of extracting light. For example, points or notches may be provided. In addition, the light-exit surfaces may also be roughened. The structurings usually have a depth in the range of from 0.1 μm to 1000 μm, in particular from 1 μm to 100 μm.

The amount of extracted light depends on the amount of particles in the plastic matrix. The greater this amount, the greater the probability that light will be extracted from the light guide. The effect of this is that the amount of particles depends on the size of the light-exit surface. The greater the dimension of the light-guide body perpendicular to the light-entry surface, the smaller the selected amount of particles in the light-guiding layer.

The extraction of the light furthermore depends on the density of the structurings of the light-exit surface, or its roughness. The denser this structuring, the higher the extraction probability of light from the light guide.

The density of the structuring may be selected to be constant over the entire surface. Very uniform luminance will nevertheless be achieved by the present invention.

It is furthermore possible to increase the density of the structuring with the distance from the light source, in order to obtain more uniform luminance. Compared with conventional light guides, however, the density change can be selected to be substantially less, since the light guides according to the invention inherently have more uniform luminance distribution.

The term “density of the structuring” means the number of points or notches per unit surface area. In general, a plate has about from 1 to 100,000 notches, in particular from 100 to 10,000 per m², but without thereby implying any limitation.

According to a particular aspect of the present invention, the scattering-means concentration may be adjusted in such a way that from 1 to 80%, in particular from 2 to 50% of the luminance on the plate surface is generated by the scattering means embedded in the polymer, and from 99 to 20%, in particular from 98 to 50% of it is generated by the structuring of the light-exit surface.

According to a preferred aspect of the present invention, the light-guide body may have a slab-shaped configuration, the three dimensions of the body having a different size.

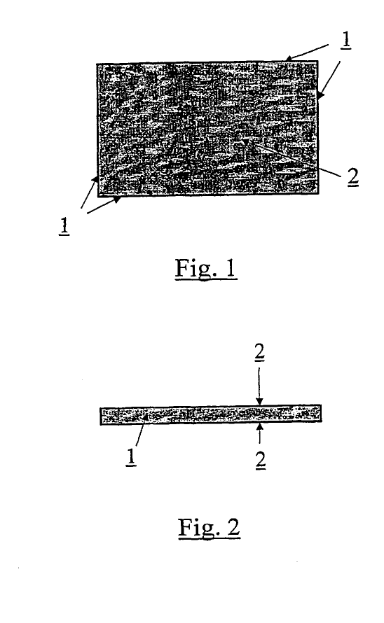

Such a slab is schematically represented, for example, in FIGS. 1 and 2. In this case, the reference number 1 denotes the edge surfaces of the slab, which may respectively be used as light-entry surfaces. Reference number 2 describes the light-exit surface of the slab.

The smallest dimension is in this case the thickness of the slab. The largest dimension is defined as length, so that the third dimension represents the width. The effect of this is that the light-exit surface of this embodiment is defined by an area which corresponds to the product of length*width. The edge surfaces of the slab, respectively defined as an area which is formed by the product of length*thickness or width*thickness, may in general be used as a light-exit surface. The edge surfaces used as a light-entry surface are advantageously polished.

Preferably, such a light-guide body has a length in the range of from 25 mm to 3000 mm, advantageously from 50 to 2000 mm and particularly preferably from 200 to 2000 mm.

The width of this particular embodiment is generally in the range of from 25 to 3000 mm, preferably from 50 to 2000 mm and particularly preferably from 200 to 2000 mm.

Such a light-guide body has in general a thickness of more than 2 mm, advantageously in the range of from 3 to 100 mm and particularly preferably from 3 to 20 mm, but without thereby implying any limitation. Besides these cubic versions, however, versions tapering toward one side, which have the shape of a wedge, are also conceivable. With the wedge shape, light is in general put in only over one light-entry surface.

Depending on the arrangement of the light sources, the light may in this case be shone in over all four edge surfaces. This may be necessary, in particular, in the case of very large light-guide bodies. For smaller light-guide bodies, one or two light sources are generally sufficient.

According to a preferred embodiment of the present invention, the light-exit surface is perpendicular to the light-entry surface.

In order to better exploit the light energy which is used, the edge surfaces which are not provided with a light source may be reflectively configured. This configuration may be obtained, for example, by using reflective adhesive tapes. A reflective coating may furthermore be applied to these edge surfaces.

According to a particular embodiment of the present invention, the light-guide body consists of the light-guiding layer, in which case the edge surfaces of the light-guiding layer may optionally be reflectively configured.

The light-guide body and the light-guiding layer have outstanding mechanical and thermal properties. These properties comprise, in particular, a Vicat softening point according to ISO 306 (B50) of at least 95° C. and a Young's modulus according to ISO 527-2 of at least 2000 MPa.

The light-guide body of the present invention may be used, in particular, for the illumination of LCD displays, information signs and advertising placards.

All known light sources may be used for illuminating the light-entry surface. Point-like incandescent lamps, for example low-voltage halogen incandescent lamps, one or more ends of light guides, one or more light-emitting diodes, as well as tubular halogen lamps and fluorescent tubes, are suitable. These may be arranged, for example, in a frame on one edge, or an edge surface or end surface of the light-guide body, at the side of the surface to be lit indirectly.

For better illumination of the light-guide body, the light sources may be provided with reflectors.

The luminance distribution may, for example, be determined according to the following method. After having produced a light-guiding plate provided with scattering means and surface structuring, a plate strip with a length of 595 mm, a width of 84 mm and a thickness of 8 mm are cut from the plate.

The plate strip was polished with a high luster on the four edge surfaces. The two polished 595 mm long edge surfaces are provided with a reflective adhesive tape (9) from the manufacturer 3M (type: Scotch brand 850), so that light rays which strike these edge surfaces are reflected into the plate.

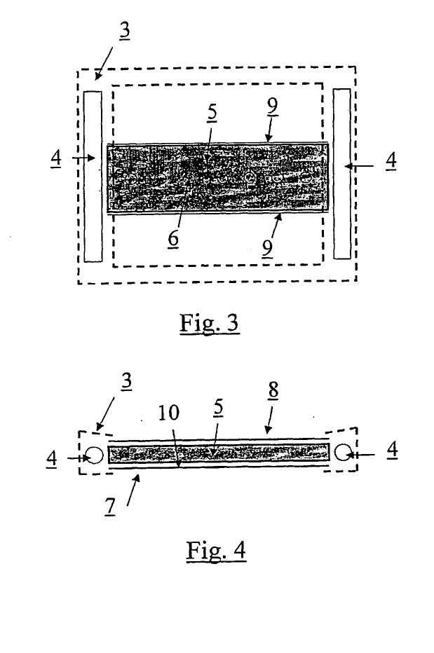

The plate strips (5) are analyzed in special measuring equipment, which is represented in FIGS. 3 and 4. The measuring equipment consists of a rectangular aluminium frame with a length of 708 mm and a width of 535 mm (3). Two respective fluorescent tubes (4) of the type PHILIPS TLD 15W/4, arranged mutually parallel, are in each case fitted to the edge of the aluminum frame, which has a width of 535 mm.

The spacing of the fluorescent tubes is 599 mm, and it is designed so that the plate strips can be placed centrally between the fluorescent tubes, and so that the light emitted by the fluorescent tubes shines into the 84 mm wide edge of the plate strips. A plate (7) with a white reflective surface (10) is fitted below the plate strips (5). The white surface is intended to reflect, toward the observer, light which emerges from the surface of the plate strip (5) on the other side from the observer. Above the plate strips (5), facing the observer, the plate strip is provided with a diffuser film (8) with a thickness of 0.5 mm, which homogenizes the light that emerges from the plate strip in the direction of the observer.

7 measurement points (6) are marked on the diffuser film, at which the luminance is measured using a luminance meter of the type MINOLTA LUMINANCE METER 1°. The measurement points are at the following distances from one of the 84 mm long edges of the plate strip: 74 mm; 149 mm; 223 mm; 298 mm; 372 mm; 446 mm; 521 mm.

1. Light-guide body which has at least one light-entry surface and at least one light-exit surface, the ratio of the light-exit surface area to the light-entry surface area being at least 4, comprising at least one light-guiding layer, wherein the light-guiding layer comprises at least 60% by weight, expressed in terms of the weight of the light-guiding layer, of polymethyl methacrylate and from 0.0001 to 0.2% by weight, expressed in terms of the weight of the light-guiding layer, of spherical particles with an average diameter in the range of from 0.3 to 40 μm, and the light-exit surface of the light-guiding layer is provided with structurings.

2. Light-guide body according to claim 1, wherein the ratio of the light-exit surface area to the light-entry surface area is at least 20.

3. Light-guide body according to claim 1, wherein the thickness of the light-guiding layer is in the range of from 2 to 100 mm.

4. Light-guide body according to claim 1, wherein the particles are made of barium sulfate, plastic, or both barium sulfate and plastic.

5. Light-guide body according to claim 4, wherein the plastic particles comprise crosslinked polystyrene.

6. Light-guide body according to claim 1, wherein the light-exit surface has uniform structurings.

7. Light-guide body according to claim 1, wherein the light-exit surface has nonuniform structurings.

8. Light-guide body according to claim 1, wherein the structurings of the light-exit surface are in point form and/or in line form.

9. Light-guide body according to claim 1, wherein the light-guide body comprises at least 90% by weight, expressed in terms of the weight of the light-guide body, of polymethyl methacrylate.

10. Light-guide body according to claim 1, wherein the particles have an average diameter in the range of from 1.4 to 10 μm.

11. Light-guide body according to claim 1, wherein the light-guiding layer has from 0.0005 to 0.08% by weight, expressed in terms of the weight of the light-guiding layer, of spherical particles.

12. Light-guide body according to claim 1, wherein the polymethyl methacrylate of the light-guiding layer has a refractive index at the Na-D line (589 nm) and at 20° C. in the range of from 1.48 to 1.54.

13. Light-guide body according to claim 1, wherein the light-guiding layer has a transmission according to DIN 5036 in the range of from 75 to 92%.

14. Light-guide body according to claim 1, wherein the light-exit surface is perpendicular to the light-entry surface.

15. Light-guide body according to claim 1, wherein at least one surface, which is parallel to the light-entry surface, is configured with a reflective layer.

16. Process for producing a light-guide body according to claim 1, wherein a molding composition having at least 60% by weight, expressed in terms of the weight of the molding composition, of polymethyl methacrylate and from 0.0001 to 0.2% by weight, expressed in terms of the weight of the molding composition, of spherical particles with an average diameter in the range of from 0.7 to 40 μm, is thermoplastically molded.

17. Process for producing a light-guide body according to claim 1, wherein an acrylic resin having
A) 0.0001-0.2% by weight of spherical particles with an average diameter in the range of from 0.7 to 40 μm,
B) 40-99.9999% by weight of methyl methacrylate,
C) 0-59.9999% by weight of comonomers,
D) 0-59.9999% by weight of polymers soluble in (B) or (C),
the components A) to D) adding up to 100%, is radical-polymerized.

18. Device for indirect lighting having at least one light-guide body according to claim 1, and a light source, which can illuminate the light-entry surface of the light-guide body.
